(19) United States
(12) Patent Application Publication
(10) Pub. No.: US 2018/0374547 A1
(43) Pub. Date: Dec. 27, 2018

(54) HANDLING OF THE THERMAL DISPARITY ACROSS MULTIPLE PACKAGES IN HIGH CAPACITY SSD

(71) Applicant: Western Digital Technologies, Inc., San Jose, CA (US)

(72) Inventors: Nian Niles YANG, Mountain View, CA (US); Philip David REUSSWIG, Mountain View, CA (US); Mrinal KOCHAR, San Jose, CA (US); Varuna KAMILA, San Jose, CA (US)

(21) Appl. No.: 15/630,646

(22) Filed: Jun. 22, 2017

(51) Int. Cl. G11C 16/34; G11C 7/04; G06F 3/06; G05D 23/19

(52) U.S. Cl. CPC G11C 16/3418; G05D 23/193; G06F 3/0653; G11C 7/04

(57) ABSTRACT

The temperature of the various devices on a printed circuit board (PCB) can change over time as the PCB is used. Additionally, the various devices on the PCB can have different temperatures at the same time. For example, the closer a device is to a heat source, the greater the temperature. Similarly, the further away from the heat source, the lower the temperature. Thus, otherwise identical devices on a PCB can have different temperatures at the same time, and additionally, the temperatures can change over time. By periodically measuring the temperature of the devices, the thermal disparity for the devices can be efficiently and intelligently managed.

### BACKGROUND OF THE DISCLOSURE

### Field of the Disclosure

Embodiments of the present disclosure generally relate to handling thermal disparities in memory devices such as solid state drives (SSDs).

### Description of the Related Art

Flash memory SSDs have advantages over traditional hard disk drives (HDDs) in that SDDs have a higher throughput, lower read/write latency and lower power consumption. NAND flash memories in particular have a low price and a large capacity compared to other non-volatile memories (NVMs).

High performance and high capacity SSDs use multiple packages with multiple NAND dies in each package while maintaining a full parallelism on all the dues during high performance operations (e.g., programming thirty-two dies across eight channels on four packages simultaneously). The flash memory used in the SSD system will experience localized temperature disparity effect which lead to system behavior disparities. Subsequently, the data integrity of the non-volatile memory is impacted. Specifically, the data retention and bit error rate variation in different NAND dies is impacted.

There is a need in the art to handle the thermal disparity, especially for high capacity drives where there are a large number of NAND flash memory packages and dies used simultaneously.

### SUMMARY OF THE DISCLOSURE

The temperature of the various devices on a printed circuit board (PCB) can change over time as the PCB is used. Additionally, the various devices on the PCB can have different temperatures at the same time. For example, the closer a device is to a heat source, the greater the temperature. Similarly, the further away from the heat source, the lower the temperature. Thus, otherwise identical devices on a PCB can have different temperatures at the same time, and additionally, the temperatures can change over time. By periodically measuring the temperature of the devices, the thermal disparity for the devices can be efficiently and intelligently managed.

In one embodiment, a memory device comprises a printed circuit board; a plurality of non-volatile memory packages coupled to the printed circuit board, wherein each non-volatile memory package includes a plurality of non-volatile memory dies and wherein each non-volatile memory die includes a plurality of blocks; and a controller coupled to the printed circuit board. The controller is configured to process a plurality of read/write operations; monitor a temperature of each non-volatile memory package; set up flags for all non-volatile memory packages that have a temperature exceeding a predetermined threshold temperature; and obtain read conditions for each block of the plurality of blocks.

In another embodiment, a memory device comprises a printed circuit board; a plurality of non-volatile memory packages coupled to the printed circuit board, wherein each non-volatile memory package includes a plurality of non-volatile memory dies and wherein each non-volatile memory die includes a plurality of blocks; and a controller coupled to the printed circuit board. The controller is configured to process a plurality of read/write operations; monitor a temperature of each non-volatile memory package; and obtain cell threshold voltage distribution for each block.

In another embodiment, a memory device comprises a printed circuit board; a plurality of non-volatile memory packages coupled to the printed circuit board, wherein each non-volatile memory package includes a plurality of non-volatile memory dies and wherein each non-volatile memory die includes a plurality of blocks; means for obtaining temperature information for each non-volatile memory package; means for mapping out each non-volatile memory die location on the printed circuit board; means for forming jumbo blocks; and means for adjusting read conditions based upon the temperature information.

In another embodiment, a method comprises measuring a temperature of a first non-volatile memory package of a plurality of non-volatile memory packages on a memory device; determining the temperature of the first non-volatile memory package is greater than a predetermined temperature zone threshold; and setting a flag for the first non-volatile memory package to indicate that the temperature is greater than the predetermined temperature zone threshold.

In another embodiment, a method comprises obtaining temperatures of each non-volatile memory package of a plurality of non-volatile memory packages on a memory device; determining the obtained temperature does not match a temperature corresponding to a threshold voltage distribution; determining whether a program/erase cycle is higher or lower than the threshold and scan to obtain new read biases; and read data of at least one non-volatile memory package.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1A is a schematic illustration of a PCB according to one embodiment.

FIG. 1B is a schematic illustration of a non-volatile memory package of FIG. 1A according to one embodiment.

FIG. 2 is a graph showing a temperature reading over time for the various components of FIG. 1A.

FIG. 3 is a schematic illustration of a jumbo block formation across four non-volatile memory packages according to one embodiment.

FIG. 4 is a flow chart illustrating a program operation according to one embodiment.

FIG. 5 is a flow chart illustrating a read operation according to one embodiment.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

In the following, reference is made to embodiments of the disclosure. However, it should be understood that the disclosure is not limited to specific described embodiments. Instead, any combination of the following features and elements, whether related to different embodiments or not, is contemplated to implement and practice the disclosure. Furthermore, although embodiments of the disclosure may achieve advantages over other possible solutions and/or over the prior art, whether or not a particular advantage is achieved by a given embodiment is not limiting of the disclosure. Thus, the following aspects, features, embodiments and advantages are merely illustrative and are not considered elements or limitations of the appended claims except where explicitly recited in a claim(s). Likewise, reference to “the disclosure” shall not be construed as a generalization of any inventive subject matter disclosed herein and shall not be considered to be an element or limitation of the appended claims except where explicitly recited in a claim(s).

The temperature of the various devices on a printed circuit board (PCB) can change over time as the PCB is used. Additionally, the various devices on the PCB can have different temperatures at the same time. For example, the closer a device is to a heat source, the greater the temperature. Similarly, the further away from the heat source, the lower the temperature. Thus, otherwise identical devices on a PCB can have different temperatures at the same time, and additionally, the temperatures can change over time. By periodically measuring the temperature of the devices, the thermal disparity for the devices can be efficiently and intelligently managed.

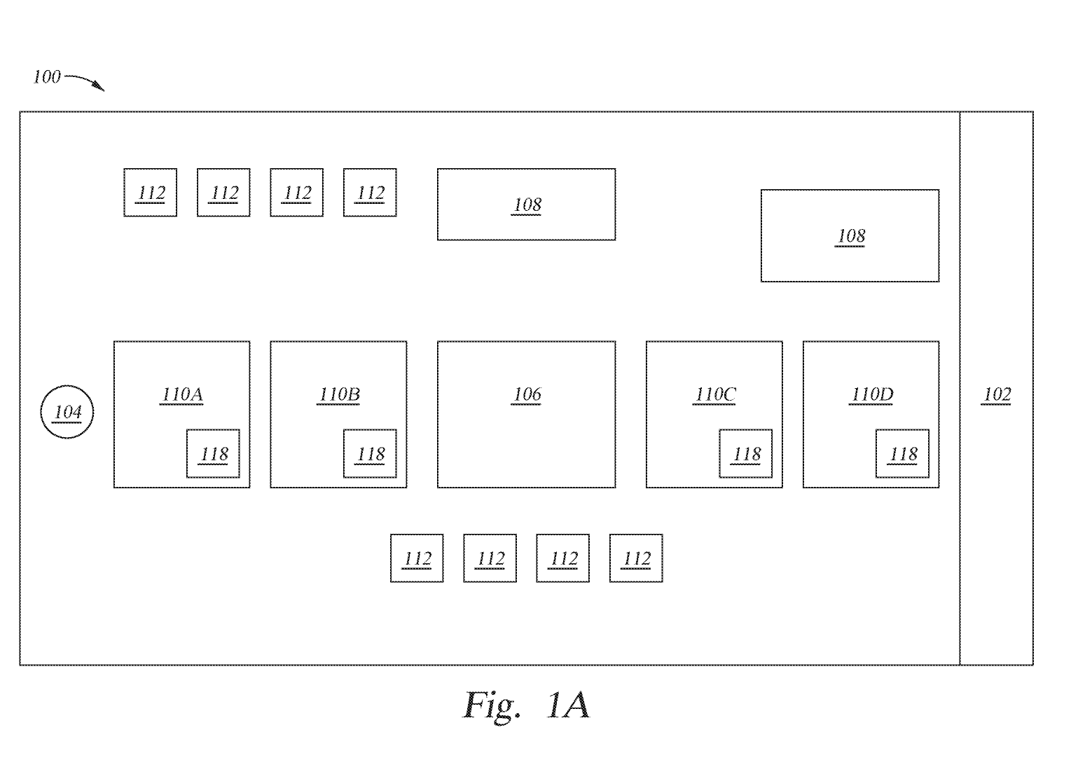

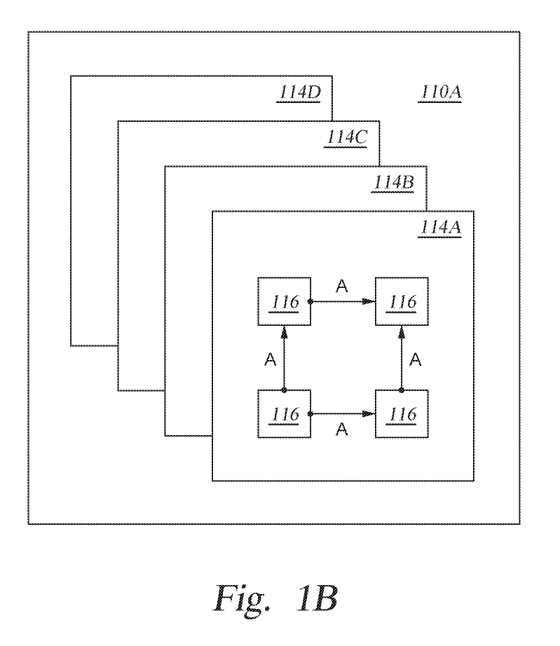

FIG. 1A is a schematic illustration of a PCB 100 according to one embodiment. The PCB 100 includes an interface portion 102 for connection to the host device. A coupling location 104 is also present to additionally secure the PCB 100 in place. The PCB 100 has an application specific integrated circuit (ASIC) 106 disposed thereon. A power integrated circuit (IC) 108 is also present. A plurality of non-volatile memory packages 110 are also disposed on the PCB 100. Finally, additional other miscellaneous items 112 are present. The miscellaneous items 112 may include GPIO, high voltage regulators, capacitors, and/or DRAM. Each package 110A-110D has a controller 118 which is coupled to a controller 120 for the PCB 100.

FIG. 1B is a schematic illustration of a non-volatile memory package 110 of FIG. 1A according to one embodiment. In one embodiment, the non-volatile memory package 110 is a NAND package. Each non-volatile memory package 110 includes a plurality of dies 114A-114D. In one embodiment, each die 114A-114D is a flash memory die. Each individual die 114A-114D includes a plurality of blocks 116. The arrows “A” are a generic representation to indicate that additional blocks are present, but simply not shown for clarity purposes. It is to be understood that each package 110 may contain more than four dies. Additionally, it is to be understood that each die 116 may contain more than four blocks. Four dies 114A-114D and four blocks 116 have been shown for clarity purposes.

The location of any given item on the PCB 100, such as a package 110, impacts the temperature of the item. Furthermore, the proximity to other items on the PCB 100 also impacts the temperature. For example, the interface portion 102 is a heat sink as is the coupling location 104. The ASIC 106 generates heat as does the power IC 108. Hence, not only with the usage of the package 110 impact the temperature of the package 110 and dies 114A-114D, but the temperatures of the surrounding devices will also impact the temperature of the package 110 and dies 114A-114D.

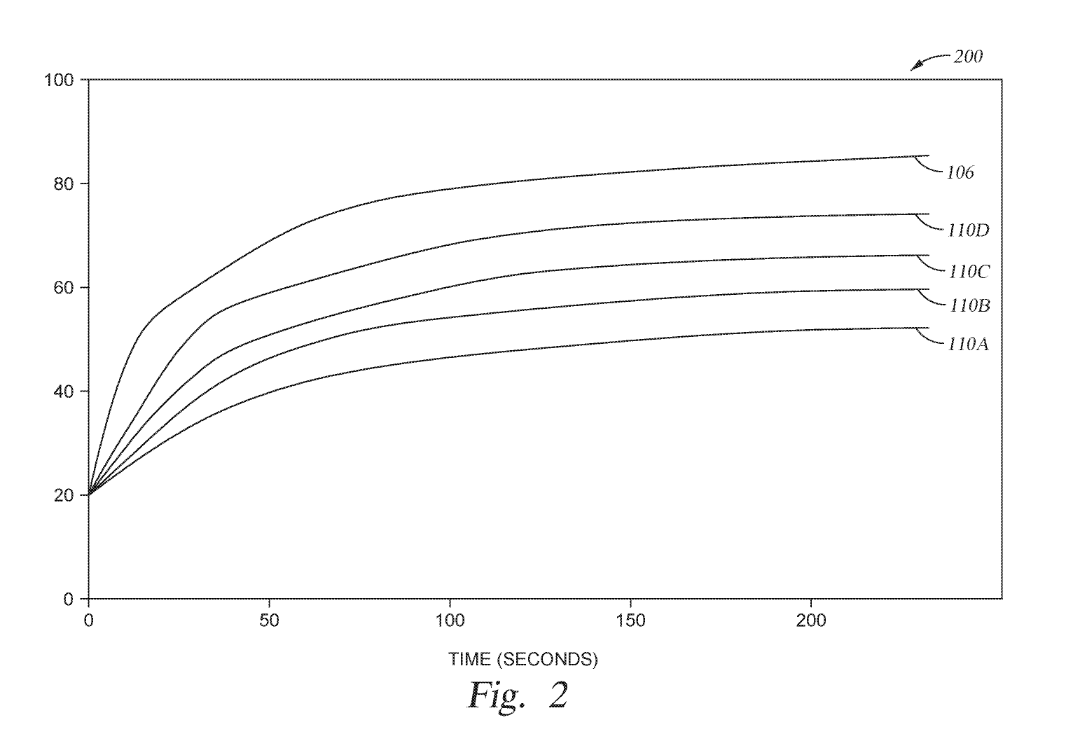

FIG. 2 is a graph 200 showing a temperature reading over time for the various components of FIG. 1A. As shown in FIG. 2, the ASIC 106 has the highest temperature over time. Additionally, the ASIC 106 ramps up the temperature faster than any other component measured. Contrasting the ASIC 106 temperature with the package 110A-110D temperatures, the temperate for the various packages 110A-110D is lower over time, and the temperature increase is slower than the ramp up for the ASIC 106. In regards to the specific packages, not only is package 110A the slowest package 110A-110D to ramp up temperature, but the highest temperature achieved is the lowest temperature shown on the graph 200. Correspondingly, package 110A is the farthest package 110A-110D away from the interface portion 102, which as discussed above is a heat sink. As shown in the graph 200, the closer that the package 110A-110D is to the interface portion 102, the higher the temperature and the faster the temperature ramping.

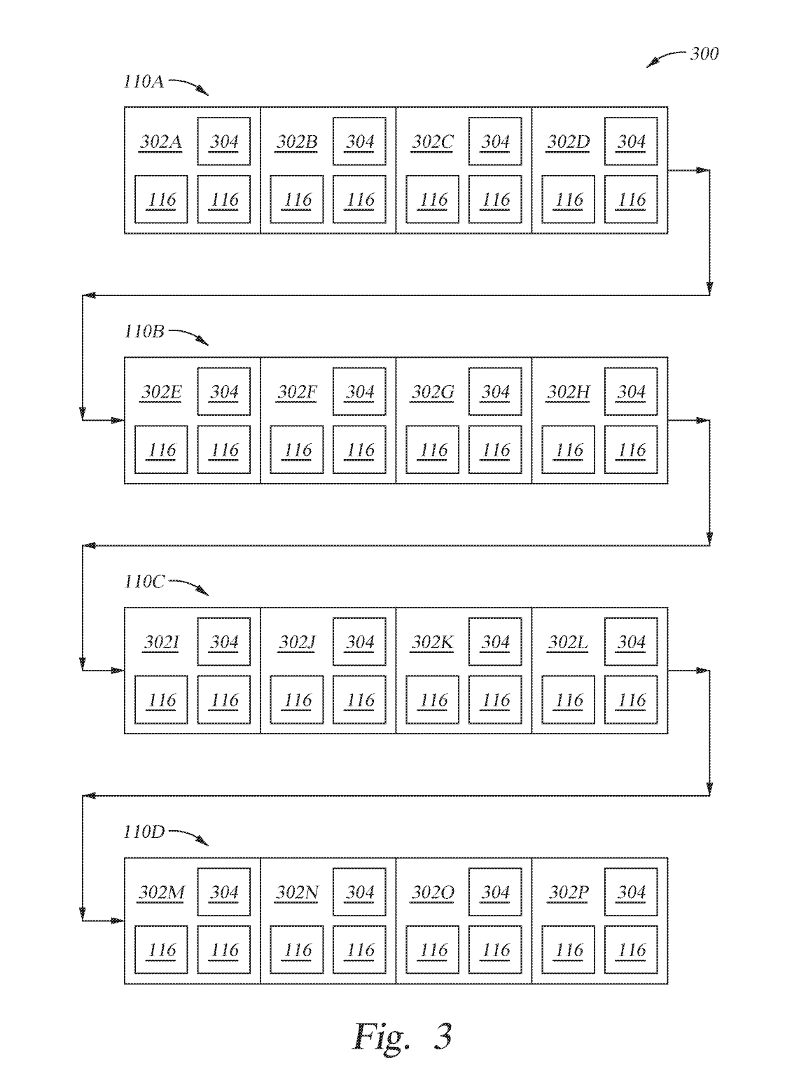

FIG. 3 is a schematic illustration of a jumbo block (JB) 300 formation across four non-volatile memory packages 110A-110D according to one embodiment. Package 110A has dies 302A-302D, Package 110B has dies 302E-302H, package 110C has dies 302I-302L, and package 110D has dies 302M-302P. The packages 110A-110D, and more specifically the dies 302A-302P, collectively form a JB 300. Thus, the JB 300 includes dies 302A-302P from each package 110A-110D without including each die that is present in each package 110A-110D. It is to be understood that a JB is not to be limited to four packages and sixteen dies. Rather, the JB 300 shown in FIG. 3 is merely for exemplification purposes and should not limit the number of packages in a JB, the number of dies in a JB or the number of blocks in a JB.

Similar to the temperature distribution shown in FIG. 2, the temperature of the individual dies 302A-302P increases the closer the die gets to the interface portion 102. Hence, within an individual package, individual dies can have different temperatures. For example, within package 110A, die 302A has a lower temperature than die 302B, die 302B has a lower temperature than die 302C, and die 302C has a lower temperature than die 302D. Similarly, within package 110B, die 302E has a lower temperature than die 302F, die 302F has a lower temperature than die 302G, and die 302G has a lower temperature than die 302H. Additionally, within package 110C, die 302I has a lower temperature than die 302J, die 302J has a lower temperature than die 302K, and die 302K has a lower temperature than die 302L. Finally, within package 110D, die 302M has a lower temperature than die 302N, die 302N has a lower temperature than die 302O, and die 302O has a lower temperature than die 302P. The temperatures discussed above are at any given point in time after time 0. Taking the temperature distribution from adjacent packages into consideration, die 302D has a lower temperature than die 302E, die 302H has a lower temperature than die 302I, and die 302L has a lower temperature than die 302M.

Because the individual dies 302A-302P have different temperatures at any given time past time 0, the read and write conditions for each die may be different. Thus, each individual die 302A-302P have a temperature sensor 304 that reports temperature data back to the controller 118 for the package 110A-110D. The temperature of each individual die is monitored periodically, for example every second, to determine the temperature at any given point in time for any given die. Based upon the temperature feedback measurements, the temperature for each die is tracked and stored in an SSD management table, and the system maps out the physical die's location and the channel to which the die belongs. Thus, every time a JB is formed, the information, such as which die and channel, about the individual physical blocks becomes available as well. Therefore, the system knows which channel or die tends to become hot more quickly than other channels or dies. The system becomes aware of which physical blocks of a given JB tends to become hotter as compared to others. The system sets up predefined temperature zones for each package (or each channel) because the predefined temperature zones will follow different temperature profiles.

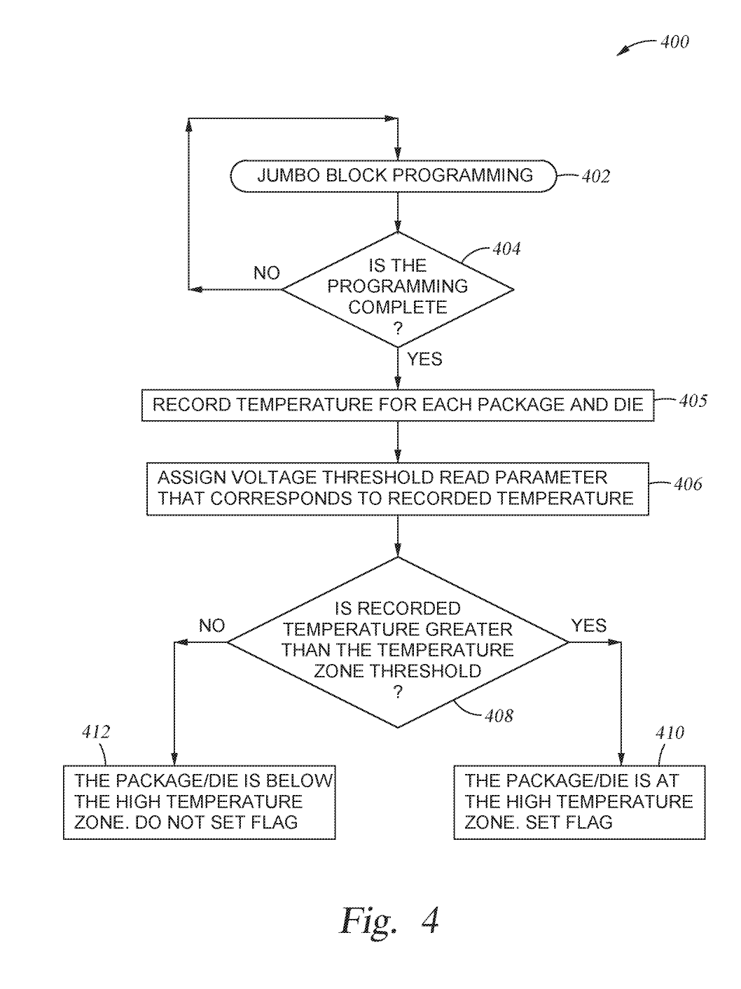

FIG. 4 is a flow chart 400 illustrating a program operation according to one embodiment. As shown in the flow chart 400, the JB is initially programmed in block 402. If the block is not closed in block 404, then the JB programming continues. If the block is closed in block 404, then the temperature for each package and/or die is measured and then recorded in a table in block 405. A voltage threshold that corresponds to each temperature is also recorded in the table in block 406. If the package and/or die temperature is greater than the high temperature threshold in block 408, then the package and/or die is in the high temperature zone and thus, the flag is set in block 410. If, however, the temperature in block 408 is not greater than the high temperature threshold, then the flag is not set in block 412. In a more basic sense, the flags are set for all packages and/or dies that show a temperature exceeding the high temperature zone threshold at the completion of JB programming. The flow chart 400 provides the optimum read conditions based upon the measured temperature. The optimum read conditions are generally obtained by using the cell threshold voltage distribution for each physical block of the JB, checking the package and/or die high temperature zone flag and mark the read conditions with the high temperature zone flag for the package and/or die. The JB will thus contain physical blocks that are programmed at different temperature zones and thus will have different optimum read conditions per temperature. To effectively implement the procedure, the temperature is measured periodically. In one embodiment, the temperature is measured every second. Each time the temperature is measured, the table is updated with the current temperature. Thus, the table will contain the most recent temperature measurement, the high temperature zone threshold information, the flag information and the threshold voltage distribution.

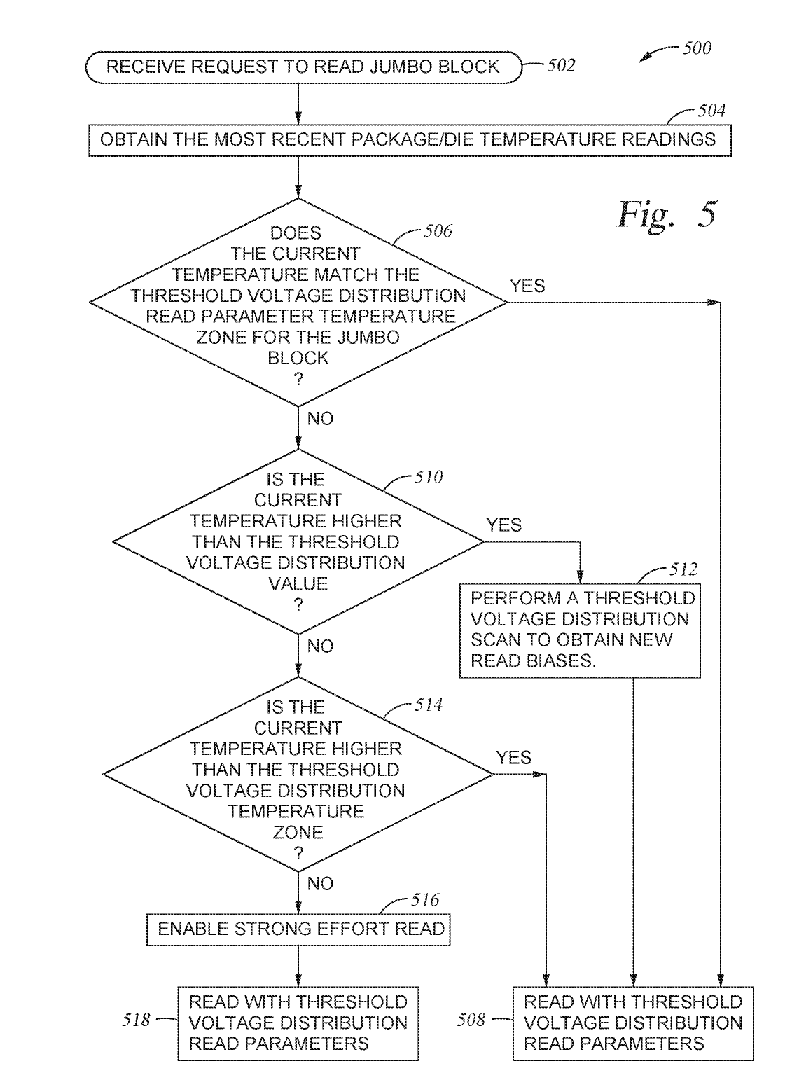

FIG. 5 is a flow chart 500 illustrating a read operation according to one embodiment. The read operation begins at block 502 where an instruction to read a JB is received. The temperature for the affected dies/packages needs to be known to accurately perform the read operation. Therefore, at block 504, the temperatures are obtained. A determination needs to be made in regards to whether the temperature matches the threshold voltage distribution read parameter temperature zone value in block 506. Basically, in block 506, the high temperature flags are checked for all packages/dies to see if the flags match with the current temperature. If there is a match, then in block 508, the read proceeds with the threshold voltage distribution read parameters. If there is no match, then a determination is made regarding whether the current temperature is higher than the threshold voltage distribution read parameter temperature zone value in block 510. If the current temperature is higher than the voltage distribution read parameter temperature zone value, then in block 512, a threshold voltage distribution scan is performed to obtain new read biases. Thereafter, the read is performed with the threshold voltage distribution read parameter values in block 508. If the temperature in block 510 is not determined to be higher than the threshold voltage distribution read parameter temperature zone value, then a determination is made in block 514 as to whether the current temperature is higher than the threshold voltage distribution temperature zone. If the value is yes, then the read is performed in block 508. If the value is no for block 514, then a strong effort read is enabled in block 516. The strong effort read is a DLA (or read bias adjustment). Alternatively, a soft bit read occurs immediately. Assuming the strong effort read proceeds, then the read will occur in block 518, but the read will be with the threshold voltage distribution read parameters as hard bits with the strong effort measure.

TABLE I

| | | Package | Package | Package | Package |
|---|---|---|---|---|---|
| | Read | 0 HT | 1 HT | 2 HT | 3 HT |
| | bias | zone | zone | zone | zone |
| JB ID # | level | flag | flag | flag | flag |
| 1 | 1 | 0 | 0 | 0 | 0 |
| 2 | 1 | 0 | 0 | 0 | 1 |
| 3 | 1 | 0 | 0 | 1 | 1 |
| 4 | 1 | 0 | 1 | 1 | 1 |
| 5 | 1 | 1 | 1 | 1 | 1 |

Table I exemplifies the read parameters determined following a JB programming events. For JB ID #1, all packages are cold at programming and thus have a “0” value. Therefore, when reading JB ID #1, the read can occur with the voltage threshold distribution read values. However, for JB ID #2, Package 3 has a flag set because Package 3 is hot at programming. Therefore, when reading JB ID #2, the read parameters for Package 3 need to be adjusted while the read parameters for Packages 0-2 are the voltage threshold distribution read values. For JB ID #3, both Package 2 and Package 3 are hot at programming as exemplified by the “1” value. Thus, when reading JB ID #3, Packages 0 and 1 are read using the voltage threshold distribution read values while Packages 2 and 3 are read based upon adjusted read parameters. For JB ID #4, Packages 1-3 are all hot at programming while Package 0 is cold. Therefore, Package 0 can be read using the voltage threshold distribution read values while Packages 1-3 are read based upon adjusted read parameters. Finally, for JB ID #5, all packages are hot at programming. Thus, for JB ID #5, all read parameter values are adjusted for reading. For the example shown in Table I, the threshold read parameters for the JBs encompass multiple physical blocks from multiple NAND packages. The adjusted read parameters include an offset. Basically, if the voltage threshold distribution value is expected to be “x” when cold, the read value will need to be “x+Δx”. If the read value is not adjusted, then a read error may occur. The reason to perform the operation shown in FIG. 4 is to be able to calculate “Δx”.

Rather than utilizing a single read voltage value, each non-volatile memory package and/or die can have unique read parameters. The unique read parameters are due to the temperature impact upon the packages and/or dies. Each package and/or die can have a different read voltage value due to the different temperatures of the packages and/or dies. By compensating for temperature disparities, more accurate reads can occur.

According to one embodiment, a memory device comprises a printed circuit board; a plurality of non-volatile memory packages coupled to the printed circuit board; and a controller coupled to the printed circuit board. The controller is configured to: process a plurality of program operations; monitor a temperature of each non-volatile memory package that has been programmed; and set up flags for all non-volatile memory packages that have a temperature exceeding a predetermined threshold temperature. The non-volatile memory packages are NAND packages. The plurality of non-volatile memory packages are disposed on the printed circuit board such that each non-volatile memory package has a different equilibrium temperature. An ASIC and an interface coupling mechanism are also present on the printed circuit board. The ASIC has an equilibrium temperature that is higher than the equilibrium temperature of each non-volatile memory package. The equilibrium temperature of a first non-volatile memory package that is disposed adjacent the interface coupling mechanism is higher than the equilibrium temperature of a second non-volatile memory package that is disposed further away from the interface coupling mechanism. Each non-volatile memory package includes a plurality of non-volatile memory dies and wherein each non-volatile memory die includes a plurality of blocks.

In another embodiment, a memory device comprises a printed circuit board; a plurality of non-volatile memory packages coupled to the printed circuit board; and a first controller coupled to the printed circuit board. The controller is configured to: process a plurality of read operations; monitor a temperature of each non-volatile memory package; and adjust a read voltage for a non-volatile memory package based upon a measured temperature of the non-volatile memory package. Each non-volatile memory package includes a plurality of non-volatile memory dies and wherein each non-volatile memory die includes a plurality of blocks. Each non-volatile memory package further includes a second controller. The second controller is configured to monitor a temperature of the non-volatile memory package. The first controller is configured to determine whether a measured temperature of a given non-volatile memory package exceeds a threshold temperature. Adjusting the read voltage includes increasing the read voltage. An increase in read voltage is different for each non-volatile memory package. In one embodiment, adjusting the read voltage comprises shifting the read voltage in a positive or negative direction to either increase or decrease the read voltage from the original read voltage. Additionally, the read voltage shift can be different for each non-volatile memory package.

According to another embodiment, a memory device comprises a printed circuit board; a plurality of non-volatile memory packages coupled to the printed circuit board; means for obtaining temperature information for each non-volatile memory package; means for mapping out each non-volatile memory die location on the printed circuit board; means for forming jumbo blocks; and means for adjusting read conditions based upon the temperature information. The device further comprises means for determining whether a measured temperature is different from a predetermined temperature. Each non-volatile memory package includes a plurality of non-volatile memory dies and wherein each non-volatile memory die includes a plurality of blocks.

In another embodiment, a method comprises measuring a temperature of a first non-volatile memory package of a plurality of non-volatile memory packages on a memory device; determining the temperature of the first non-volatile memory package is greater than a predetermined temperature; and setting a flag for the first non-volatile memory package to indicate that the temperature is greater than the predetermined temperature. The method additionally comprises measuring a temperature of a second non-volatile memory package of the plurality of non-volatile memory packages and determining the temperature of the second non-volatile memory package is less than a predetermined temperature. For the method, the flag is saved in RAM or a NAND control block. Additionally, the method comprises storing read bias levels in the RAM or NAND control block.

In another embodiment, a method comprises obtaining current temperatures of each non-volatile memory package of a plurality of non-volatile memory packages on a memory device; determining the current temperature does not match a temperature corresponding to a threshold voltage distribution; determining whether a program/erase cycle is higher or lower than the threshold voltage distribution and scan to obtain new read biases; and read data of at least one non-volatile memory package. Determining whether a program/erase cycle is higher or lower comprises: determining that the program/erase cycle is higher; and scanning to obtain new read biases. Determining whether a program/erase cycle is higher or lower alternately comprises: determining that the program/erase cycle is lower. The method additionally comprises determining the current temperature is higher than a corresponding threshold voltage distribution, determining the current temperature is lower than a corresponding threshold voltage distribution; and enabling a strong effort read. For the method, the temperature corresponding to the threshold voltage is a flag that is stored in RAM or a NAND control block. Additionally, read bias levels are stored in the RAM or NAND control block.

While the foregoing is directed to embodiments of the present disclosure, other and further embodiments of the disclosure may be devised without departing from the basic scope thereof, and the scope thereof is determined by the claims that follow.

What is claimed is:

1. A memory device, comprising:
a printed circuit board;
a plurality of non-volatile memory packages coupled to the printed circuit board; and
a controller coupled to the printed circuit board, wherein the controller is configured to:
process a plurality of program operations;
monitor a temperature of each non-volatile memory package that has been programmed; and
set up flags for all non-volatile memory packages that have a temperature exceeding a predetermined threshold temperature.

2. The memory device of claim 1, wherein the non-volatile memory packages are NAND packages.

3. The memory device of claim 1, wherein the plurality of non-volatile memory packages are disposed on the printed circuit board such that each non-volatile memory package has a different equilibrium temperature.

4. The memory device of claim 3, further comprising:
an ASIC; and
an interface coupling mechanism.

5. The memory device of claim 4, wherein the ASIC has an equilibrium temperature that is higher than the equilibrium temperature of each non-volatile memory package.

6. The memory device of claim 5, wherein the equilibrium temperature of a first non-volatile memory package that is disposed adjacent the interface coupling mechanism is higher than the equilibrium temperature of a second non-volatile memory package that is disposed further away from the interface coupling mechanism.

7. The memory device of claim 1, wherein each non-volatile memory package includes a plurality of non-volatile memory dies and wherein each non-volatile memory die includes a plurality of blocks.

8. A memory device, comprising:
a printed circuit board;
a plurality of non-volatile memory packages coupled to the printed circuit board; and
a first controller coupled to the printed circuit board, wherein the controller is configured to:
process a plurality of read operations;
monitor a temperature of each non-volatile memory package; and
adjust a read voltage for a non-volatile memory package based upon a measured temperature of the non-volatile memory package.

9. The memory device of claim 8, wherein each non-volatile memory package includes a plurality of non-volatile memory dies and wherein each non-volatile memory die includes a plurality of blocks.

10. The memory device of claim 8, wherein each non-volatile memory package further includes a second controller.

11. The memory device of claim 10, wherein the second controller is configured to monitor a temperature of the non-volatile memory package.

12. The memory device of claim 8, wherein the first controller is configured to determine whether a measured temperature of a given non-volatile memory package exceeds a threshold temperature.

13. The memory device of claim 8, wherein adjusting the read voltage includes shifting the read voltage to either increase or decrease the read voltage.

14. The memory device of claim 13, wherein the shifting the read voltage is different for each non-volatile memory package.

15. A memory device, comprising:
a printed circuit board;
a plurality of non-volatile memory packages coupled to the printed circuit board;
means for obtaining temperature information for each non-volatile memory package;
means for mapping out each non-volatile memory die location on the printed circuit board;
means for forming jumbo blocks; and
means for adjusting read conditions based upon the temperature information.

16. The memory device of claim 15, further comprising means for determining whether a measured temperature is different from a predetermined temperature.

17. The memory device of claim 16, wherein each non-volatile memory package includes a plurality of non-volatile memory dies and wherein each non-volatile memory die includes a plurality of blocks.

18. A method, comprising:
measuring a temperature of a first non-volatile memory package of a plurality of non-volatile memory packages on a memory device;
determining the temperature of the first non-volatile memory package is greater than a predetermined temperature; and
setting a flag for the first non-volatile memory package to indicate that the temperature is greater than the predetermined temperature.

19. The method of claim 18, further comprising:
measuring a temperature of a second non-volatile memory package of the plurality of non-volatile memory packages;
determining the temperature of the second non-volatile memory package is less than a predetermined temperature.

20. The method of claim 18, wherein the flag is saved in RAM or a NAND control block.

21. The method of claim 20, further comprising storing read bias levels in the RAM or NAND control block.

22. A method, comprising:
obtaining current temperatures of each non-volatile memory package of a plurality of non-volatile memory packages on a memory device;
determining the current temperature does not match a temperature corresponding to a threshold voltage distribution;
determining whether a program/erase cycle is higher or lower than the threshold voltage distribution and scan to obtain new read biases; and
read data of at least one non-volatile memory package.

23. The method of claim 22, wherein determining whether a program/erase cycle is higher or lower comprises:
determining that the program/erase cycle is higher; and
scanning to obtain new read biases.

24. The method of claim 22, wherein determining whether a program/erase cycle is higher or lower comprises:
determining that the program/erase cycle is lower.

25. The method of claim 24, further comprising determining the current temperature is higher than a corresponding threshold voltage distribution.

26. The method of claim 24, further comprising:
determining the current temperature is lower than a corresponding threshold voltage distribution; and
enabling a strong effort read.

27. The method of claim 22, wherein the temperature corresponding to the threshold voltage distribution is a set flag, wherein the flag are stored in RAM or a NAND control block.

28. The method of claim 27, wherein read bias levels are stored in the RAM or NAND control block.
